(19) United States
(12) Patent Application Publication
(10) Pub. No.: US 2013/0234201 A1
(43) Pub. Date: Sep. 12, 2013

(54) FIELD STOP STRUCTURE, REVERSE CONDUCTING IGBT SEMICONDUCTOR DEVICE AND METHODS FOR MANUFACTURING THE SAME

(71) Applicant: SHANGHAI HUA HONG NEC ELECTRONICS CO., LTD., Shanghai (CN)

(72) Inventor: Shengan Xiao, Shanghai (CN)

(73) Assignee: SHANGHAI HUA HONG NEC ELECTRONICS CO., LTD., Shanghai (CN)

(21) Appl. No.: 13/790,292

(22) Filed: Mar. 8, 2013

(30) Foreign Application Priority Data
Mar. 12, 2012 (CN) 201210064065.3

(51) Int. Cl. H01L 29/739; H01L 21/265; H01L 29/66; H01L 29/06

(52) U.S. Cl. CPC H01L 29/7393; H01L 29/06; H01L 21/265; H01L 29/66325
USPC 257/139; 257/495; 438/525; 438/135

(57) ABSTRACT

A field stop structure is disclosed. The field stop structure is divided into a three-dimensional structure by a plurality of trenches formed on a back side of a silicon substrate and hence obtains a greater formation depth in the substrate and can achieve a higher ion activation efficiency. Moreover, a first electrode region of a fast recovered diode (FRD) is formed in the trenches, thereby enabling the integration of a FRD with an insulated gate bipolar transistor (IGBT) device. Methods for forming field stop structure and reverse conducting IGBT semiconductor device are also disclosed.

### CROSS-REFERENCES TO RELATED APPLICATIONS

This application claims the priority of Chinese patent application number 201210064065.3, filed on Mar. 12, 2012, the entire contents of which are incorporated herein by reference.

### TECHNICAL FIELD

This disclosure relates in general to the field of semiconductor integrated circuit fabrication, and more particularly, to field stop structures, reverse conducting insulated gate bipolar transistor (IGBT) semiconductor devices employing the stop structures, and methods for manufacturing the same.

### BACKGROUND

Insulated gate bipolar transistors (IGBTs) have been increasingly employed among high-voltage devices having a breakdown voltage of higher than 600 volts. Moreover, recent researches on IGBTs are focused on devices with both a high breakdown voltage and a high electrical current density. In general application, an IGBT is combined with a fast recovered diode (FRD) in the process of module assembly in order to reduce its power consumption in switching operations and improve its capacity of reverse current conduction. Nowadays, some manufacturers have started to integrate the FRD into an IGBT chip so as to further increase its electrical current density, and especially for the purposes of lowering the complexity of the module assembly process, increasing the reliability of the module assembly process and reducing the size of assembled modules. A conventional approach for achieving these is to first form a P+ region which serves as a collector region of the IGBT and an N+ region which serves as a first electrode region of the FRD on a bottom surface of an N-type layer that is formed on a back side of a silicon substrate, and thereafter to perform a metallization process on bottom surfaces of both the P+ and N+ regions so as to form a collector electrode of the IGBT and a cathode of the FRD, respectively.

Moreover, in order to lower the on-resistance of the IGBT, the existing process may further include forming, by ion implantation or the like, a field stop layer in a lower part (close to the bottom surface) of the N-type layer before forming the P+ and N+ regions. For example, such field stop layer may be achieved by forming a drift layer with graded dopant concentration around the center of a drift region of the IGBT or in proximity to the back side of the silicon substrate. This can lower the on-resistance of the IGBT and hence to ensure more reliable switching characteristics for it.

FIG. 1 schematically illustrates an N-type IGBT (i.e., an IGBT with an N-type doped drift region) with a field stop layer constructed using a traditional technique. As illustrated, this device differs from a one without such field stop layer in further including an N-type field stop layer 3 between an N-type silicon substrate 1 and a P-type collector region 4. Carrier concentration in the field stop layer 3 is higher than that in the silicon substrate 1. Additionally, a portion of the silicon substrate 1 between a P-well 7 and the field stop layer 3 forms the N-type drift region of the device. The rest portion of the device is as same as the structure of the one without the field stop layer, including: the P-well 7 formed in the silicon substrate 1; an N+ source 8 formed in the P-well 7; a gate oxide 5 and a polysilicon gate 6, wherein a portion of the polysilicon gate 6 covers part of the P-well 7, and wherein a channel region is formed beneath this portion of the gate and is connected with both the N+ source 8 and the silicon substrate 1; a P+ contact implantation region 11 for picking up the P-well 7; a contact hole 10; a top metal layer 12 and a back-side metal layer 14. As illustrated in FIG. 1, the drift region is formed in the portion represented by a region between the cross sections A and B1 excluding the P-wells 7; the region between the cross sections B and C represents the field stop layer 3; the region below the cross section C represents the P-type collector region 4 and the back-side metal layer 14.

There are several methods available in traditional techniques for forming such field stop layer that consists of a graded drift layer.

For example, in one method, a field stop layer can be obtained by implanting (either from a front side or a back side) lightweight ions such as helium ions, followed by an annealing process. As the ions can reach a depth of several tens of millimeters, a field graded layer covering a wide range of depth with respect to a back side surface of the silicon substrate can be obtained.

Another method is to implant ions of an N-type dopant such as phosphorus or arsenic at the back side surface of the silicon substrate and thereafter activate the ions by an annealing process, following the completion of all needed front-side processes. In this method, the annealing process can be a high-temperature thermal annealing process or a laser annealing process. However, both of these processes have drawbacks such as, for example: the metals such as aluminum that have been formed on the front side of the silicon substrate will generally limit the annealing process to be performed at a temperature no higher than 500° C., under which temperature only a small percentage of ions can be activated; in addition, although laser annealing can help to achieve a high temperature locally on the back side surface of the substrate and hence lead to a high ion activation efficiency, due to the limited penetration ability of laser beams, only ions contained 1 μm to 2 μm deep from the back side surface can be activated when a laser annealing process is used, which fails to meet the condition of creating a field stop layer, i.e., a diffusion range of 3 μm to 30 μm of activated ions.

### SUMMARY OF THE INVENTION

The present invention is to provide a field stop structure which facilitates the increase of a formation depth and an ion activation efficiency of a field stop layer.

Moreover, the present invention is also to provide a reverse conducting insulated gate bipolar transistor (IGBT) semiconductor device with a good integration between an IGBT device and a fast recovered diode (FRD).

A first aspect of the present invention provides a field stop structure, which is formed in a silicon substrate of a first conductivity type, a plurality of trenches being formed on a back side of the silicon substrate, the field stop structure including: a first field stop layer of the first conductivity type located in a portion of the silicon substrate at bottom of the plurality of trenches, the first field stop layer being laterally continuous; and a plurality of second field stop layers of the first conductivity type, each being located between two adjacent trenches and being joined with the first field stop layer.

In one embodiment, the first conductivity type is N-type, and each of the first field stop layer and the second field stop layers contains a dopant selected from a group consisting of phosphorus, arsenic, selenium, sulfur and combinations thereof.

In one embodiment, each of the plurality of trenches has a depth of 1 μm to 50 μm, and wherein the first field stop layer has a thickness of greater than 5 μm.

In one embodiment, a ratio of a width of each trench to a spacing between adjacent trenches is 1/50 to ½.

In one embodiment, the field stop structure has a carrier concentration greater than that of the silicon substrate.

A second aspect of the present invention provides a reverse conducting IGBT semiconductor device incorporating the above-mentioned field stop structure. The IGBT semiconductor device integrates an IGBT device and an FRD and further includes: a first electrode region of the FRD consisting of a polysilicon or an epitaxial layer of the first conductivity type formed in the plurality of trenches; a collector region of the IGBT device consisting of ion implantation regions of a second conductivity type formed in top portions of the second field stop layers; and a back-side metal layer formed on the back side of the silicon substrate, the back-side metal layer being connected with the collector region of the IGBT device and the first electrode region of the FRD and serving as an electrode for the collector region of the IGBT device and the first electrode region of the FRD.

Furthermore, a third aspect of the present invention provides a method for forming a field stop structure, which includes: forming a plurality of trenches on a back side of a silicon substrate having a first conductivity type; performing, by using ions of the first conductivity type, a vertical implantation and multiple steps of tilted implantations on the back side of the silicon substrate; and performing an annealing process to activate and cause diffusion of the ions so as to form a laterally continuous first field stop layer in a portion of the silicon substrate at bottom of the plurality of trenches and a plurality of second field stop layers, each second field stop layer being located between two adjacent trenches and being joined with the first field stop layer.

In one embodiment, the first conductivity type is N-type, and the second conductivity type is P-type.

In one embodiment, each of the plurality of trenches has a depth of 1 μm to 50 μm and the first field stop layer has a thickness of greater than 5 μm.

In one embodiment, a ratio of a width of each trench to a spacing between adjacent trenches is 1/50 to ½.

In one embodiment, the N-type ions of the vertical implantation are phosphorus ions and the vertical implantation is performed with an energy of 200 KeV to 3000 KeV and a dose of 1e11 cm⁻² to 1e14 cm⁻², and wherein the multiple steps of tilted implantations are performed with at least two different angles and an implantation dose of 2e11 cm⁻² to 5e12 cm⁻².

In one embodiment, the N-type ions used in the vertical implantation are phosphorus ions and the N-type ions used in the tilted implantations are phosphorus ions or arsenic ions, and wherein the annealing process is a thermal annealing process performed at a temperature of 700° C. to 1250° C.

In one embodiment, the N-type ions used in the vertical implantation are selenium ions or sulfur ions and the N-type ions used in the tilted implantations are selenium ions or sulfur ions, and wherein the annealing process is a thermal annealing process performed for 1 hour to 10 hours at a temperature of 700 to 900.

In one embodiment, the ions are annealed using a laser annealing process.

In addition, a fourth aspect of the present invention provides a method for manufacturing a reverse conducting IGBT semiconductor device with a good integration between an IGBT device and an FRD, which includes the steps of: depositing a first dielectric film over a front side of a silicon substrate having a first conductivity type so as to protect the front side of the silicon substrate; forming a plurality of trenches on a back side of a silicon substrate; performing, by using ions of the first conductivity type, a vertical implantation and multiple steps of tilted implantations on the back side of the silicon substrate; performing an annealing process to activate and cause diffusion of the ions so as to form a laterally continuous first field stop layer in a portion of the silicon substrate at bottom of the plurality of trenches and a plurality of second field stop layers, each second field stop layer being located between two adjacent trenches and being joined with the first field stop layer; and forming a first electrode region of the FRD and a collector region of the IGBT device.

In one embodiment, the step of forming a first electrode region of the FRD and a collector region of the IGBT device includes: depositing a second dielectric film over the back side of the silicon substrate and etching back the second dielectric film such that the etched second dielectric film partially fills each of the plurality of trenches; forming ion implantation regions of a second conductivity type, which serve as the collector region of the IGBT device, in top portions of the second field stop layers, by performing an implantation of ions of the second conductivity type into the back side of the silicon substrate; removing the second dielectric film; and filling a polysilicon or an epitaxial layer of the first conductivity type, which serves as the first electrode region of the FRD, in the plurality of trenches.

In another embodiment, the step of forming a first electrode region of the FRD and a collector region of the IGBT device includes: filling a polysilicon or an epitaxial layer of the first conductivity type, which serves as the first electrode region of the FRD, in the plurality of trenches; and forming ion implantation regions of a second conductivity type, which serve as the collector region of the IGBT device, in top portions of the second field stop layers, by performing an implantation of ions of the second conductivity type into the back side of the silicon substrate.

In one embodiment, the first conductivity type is N-type and the second conductivity type is P-type.

In one embodiment, the polysilicon or the epitaxial layer has a dopant concentration of 1e19 cm⁻³ to 5e20 cm⁻³.

In one embodiment, ions of the second conductivity type are boron ions and are implanted with an energy of 30 KeV to 100 KeV and a dose of 3e14 cm⁻² to 5e15 cm⁻².

As described herein, the present invention provides a number of benefits as compared with conventional techniques, including: obtaining a three dimensional field stop layer formed deeper in the substrate by using a trench technology that incorporates a combination of a vertical implantation and multiple tilted implantations; carrying out all or part of needed front-side processes following the formation of the field stop layer, thereby allowing the use of a high-temperature annealing process to activate ions contained in the field stop layer and thus increase the activation efficiency of the field stop layer; and enabling the integration of an IGBT device and an FRD by forming a first electrode region of the FRD in the trenches.

### BRIEF DESCRIPTION OF THE DRAWINGS

To provide a more complete understanding of the present invention, reference is made to the following description on example embodiments, taken in conjunction with the accompanying drawings, in which:

FIG. 1 is a schematic illustration of a conventional field stop structure;

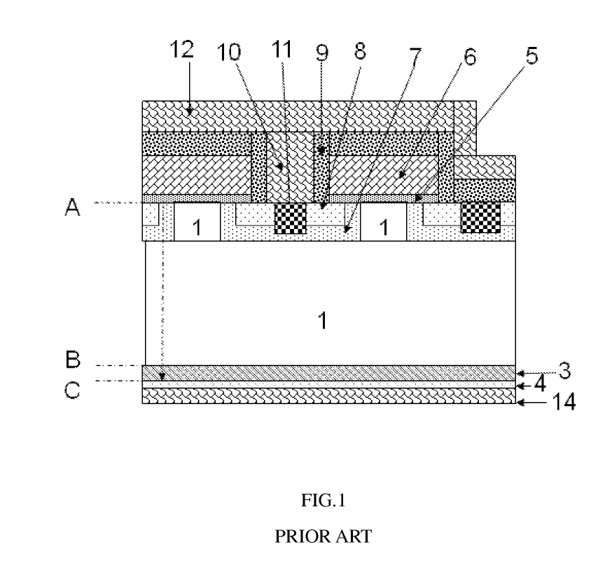

FIG. 2 is a schematic diagram illustrating a reverse conducting IGBT semiconductor device according to a first embodiment of the present invention;

FIGS. 3A to 3D illustrate semiconductor structures resulted from respective steps of the method for manufacturing a reverse conducting IGBT semiconductor device according to the first embodiment of the present invention;

FIG. 4A illustrates a dopant concentration distribution along the line D1-D1′ of FIG. 3D; and

FIG. 4B illustrates a dopant concentration distribution along the line D2-D2′ of FIG. 3D.

### DETAILED DESCRIPTION

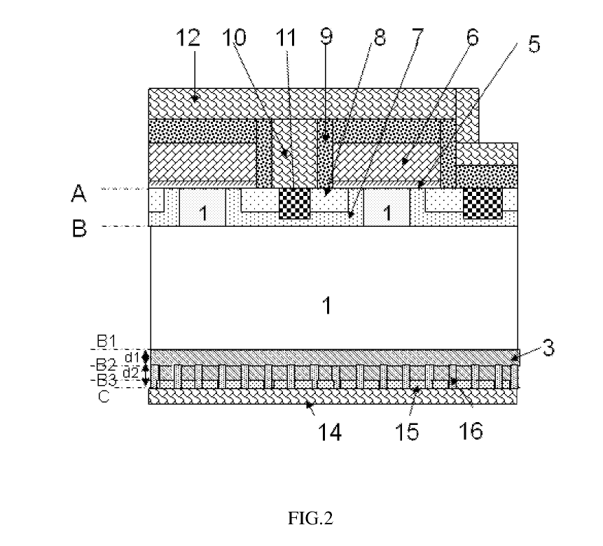

FIG. 2 illustrates a reverse conducting insulated gate bipolar transistor (IGBT) semiconductor device according to a first embodiment of the present invention, which is integrated with an IGBT device and a fast recovered diode (FRD). In this embodiment, the IGBT device is a field-stop type IGBT (FSIGBT) with a reverse breakdown voltage of 1200 volts and an N-type drift region. Herein, in a FSIGBT with an N-type drift region, N-type is defined as a first conductivity type and P-type is defined as a second conductivity type. In other embodiments, the IGBT device may be a FSIGBT with a P-type drift region, and similarly, in which P-type is defined as the first conductivity type and N-type is defined as the second conductivity type. As P-type FSIGBTs have similar features with N-type FSIGBTs, those embodiments in relation to P-type FSIGBTs will not be further specified herein.

In the first embodiment, the reverse conducting IGBT semiconductor device includes trenches formed on a back side of an N-type silicon substrate 1 such as, for example, a float zone silicon crystal. The trenches have a depth of 1 μm to 50 μm, and may preferably have a depth of 2 μm to 10 μm. Moreover, a ratio of a width of the trenches to a spacing between adjacent trenches is 1/50 to ½, and may preferably be 1/20 to ½.

The reverse conducting IGBT semiconductor device further includes an N-type field stop structure 3 that is also formed on the back side of the silicon substrate 1. The field stop structure 3 has a carrier concentration greater than that of the silicon substrate 1, and is divided by the trenches into a first field stop layer which is located in a portion of the silicon substrate at bottom of the trenches and is laterally continuous and a plurality of second field stop layers, each of which is located between two adjacent trenches and is joined with the first field stop layer. Each of the first field stop layer and the second field stop layers contains a dopant, which may be any one of phosphorus, arsenic, selenium and sulfur or combinations thereof. Moreover, the first field stop layer has a thickness of greater than 5 μm.

Furthermore, the reverse conducting IGBT semiconductor device also includes a collector region 15 of the IGBT device which is consisted of ion implantation regions formed in top portions of the second field stop layers. The collector region 15 of the IGBT device has a depth of 0.1 μm to 2 μm, and may preferably have a depth of 0.5 μm to 2 μm.

The reverse conducting IGBT semiconductor device in the first embodiment further includes a first electrode region of the FRD which is consisted of a polysilicon or an epitaxial layer 16 formed in the trenches. In this embodiment, the first electrode is an N-type region, namely, a cathode region. Moreover, the polysilicon or the epitaxial layer 16 has an N-type dopant concentration of 1e19 cm⁻³ to 5e20 cm⁻³.

In addition, the reverse conducting IGBT semiconductor device further includes a back-side metal layer 14 which is connected with both the collector region 15 of the IGBT device and the first electrode region of the FRD and serves as an electrode for the collector region 15 of the IGBT device and the first electrode region of the FRD.

Moreover, the reverse conducting IGBT semiconductor device in the first embodiment further includes on the top side: a P-well 7 formed in the silicon substrate 1; an N+ source 8 formed in the P-well 7; a gate oxide 5 and a polysilicon gate 6, wherein a portion of the polysilicon gate 6 covers part of the P-well 7, and wherein a channel region is formed beneath this portion of the gate and is connected with both the N+ source 8 and the silicon substrate 1; and a P+ contact implantation region 11 for picking up the P-well 7; a contact hole 10; and a top metal layer 12. As shown in FIG. 2, the P-well 7 is formed in a portion of the silicon substrate 1 represented by a region between the cross sections A and B; the drift region is formed in the portion represented by a region between the cross sections A and B1 excluding the P-wells 7; the region between the cross sections B1 and B3 represents the field stop structure 3, of which, a part between the cross sections B1 and B2 represents the first field stop layer that has a thickness of greater than 5 μm and the rest part between the cross sections B2 and B3 represents the second field stop layers; the collector region 15 of the IGBT device is formed in the portion represented by a region between the cross sections B3 and C; and the trenches having a depth d2 of 2 μm to 10 μm are formed in the portion represented by a region between the cross sections B2 and C.

Furthermore, in the first embodiment, the P-well 7 acts as a P-type second electrode region for the FRD and a portion of the silicon substrate 1 between the P-well 7 and the first electrode region (i.e., the polysilicon or epitaxial layer 16) serves as an I-type region for the FRD, thus constituting, together with the above described N-type first electrode region, an PIN structure of the FRD. It can be readily appreciated from this description that, in addition to the increase of a formation depth and an ion activation efficiency of the field stop layer, in the first embodiment of the present invention, the integration of an IGBT device and a FRD can be further achieved by adopting the trench technology.

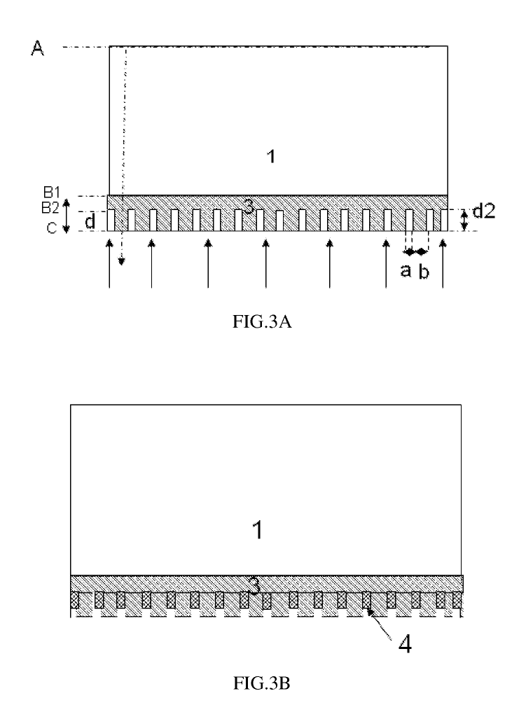

FIGS. 3A to 3D illustrate semiconductor structures resulted from respective steps of the method for manufacturing a reverse conducting IGBT semiconductor device according to the first embodiment of the present invention. Steps of the method will be specified in details in the following description.

In a first step, as illustrated in FIG. 3A, an N-type silicon substrate 1 with a dopant concentration C1 of 2.4e13 cm⁻³, a resistivity of 90 Ω·cm and a thickness of greater than 700 μm is first provided. After that, a first dielectric film (not shown) is deposited over a front side of the silicon substrate 1 so as to protect the front side. In this embodiment, the first dielectric film is an oxide film having a thickness of 5000 Å to 20000 Å.

Next, a back side of the N-type silicon substrate 1 is grinded to a desired thickness of 500 μm to 700 μm. Herein, in FIG. 3A, the cross section A represents a plane of the front side of the silicon substrate 1 whilst the cross section C represents a plane of the back side surface of the grinded silicon substrate 1.

In a second step, as shown in FIG. 3A, a plurality of trenches are formed in a portion of the back side of the silicon substrate 1 using a lithographic and etching process, wherein the portion is represented by the region between the cross sections B2 and C in the figure. The trenches have a depth d2 of 1 μm to 50 μm, and may preferably have a depth of 2 μm to 10 μm. Moreover, a ratio of a width of the trenches to a spacing b between adjacent trenches is 1/50 to ½, and may preferably be 1/20 to ½.

Thereafter, in a third step, as shown in FIG. 3A, a vertical implantation and multiple tilted implantations of N-type ions are performed in the silicon substrate 1 from the back side. The N-type ions of the vertical implantation are phosphorus ions which are implanted with an energy of 200 KeV to 3000 KeV and a dose of 1e11 cm⁻² to 1e14 cm⁻². Moreover, the N-type ions of the tilted implantations are phosphorus ions or arsenic ions, and the tilted implantations may be performed with at least two different angles. In a preferred embodiment, the multiple tilted implantations may adopt a combination of 10-degree-tilted implantation(s) and 45-degree-tilted implantation(s) and are performed at a dose of 2e11 cm⁻² to 5e12 cm⁻².

Next, in a fourth step, as shown in FIG. 3A, a field stop structure 3 is formed by activating the ions implanted into the substrate by using an annealing process for facilitating their diffusion. In this embodiment, the annealing process is a thermal annealing process performed for 2 hours to 10 hours at a temperature of 700° C. to 1250° C., and may preferably be 1100° C. to 1250° C. In another embodiment, the annealing process in this step may be a laser annealing process.

The field stop structure 3 is formed in a portion of the silicon substrate 1 with a thickness of d represented by the region between the cross sections B1 and C in the figure. Additionally, the field stop structure 3 is divided by the trenches into a first field stop layer located at bottom of the trenches and a plurality of second field stop layers each located between two adjacent trenches. Furthermore, the first field stop layer is formed in a portion represented by the region between the cross sections B1 and B2 and has a thickness of greater than 5 μm.

After that, in a fifth step, as shown in FIG. 3B, a second dielectric film 4 is deposited over the back side of the silicon substrate 1 where the field stop structure 3 has been formed; and thereafter the second dielectric film 4 is etched back such that the etched second dielectric film 4 partially fills each of the trenches, or in other words, the etched second dielectric film 4 fills part of the depth of the trenches.

Next, in a sixth step, as shown in FIG. 3C, P-type ions are implanted in the silicon substrate 1 from the back side to form ion implantation regions, which serve as a collector region 15 of the IGBT device, in top portions of the second field stop layers. In this embodiment, the P-type ions implanted for forming the collector region 15 are boron ions which are implanted with an energy of 30 KeV to 100 KeV and a dose of 3e14 cm⁻² to 5e15 cm⁻². Moreover, the collector region 15 has a depth of 0.1 μm to 2 μm, and may preferably have a depth of 0.5 μm to 2 μm.

Thereafter, in a seventh step, as shown in FIG. 3D, the second dielectric film 4 is removed.

Next, in an eighth step, as shown in FIG. 3D, an N-type polysilicon or epitaxial layer 16 is deposited, which completely fills the trenches and covers the rest portion of the back side surface of the silicon substrate 1 as well as the first dielectric film on the front side of the silicon substrate 1. Additionally, the polysilicon or epitaxial layer 16 has an N-type dopant concentration of 1e19 cm⁻³ to 5e20 cm⁻³.

After that, in a ninth step, the polysilicon or epitaxial layer 16 over the first dielectric film on the front side of the silicon substrate 1 is removed.

In a tenth step, as shown in FIG. 3D, the polysilicon or epitaxial layer 16 higher than the trenches and over the rest portion of the back side surface of the silicon substrate 1 is removed, so that only N-type polysilicon or epitaxial layer 16 that completely fills the trenches and serves as a first electrode region of the FRD is remained. The first electrode region is an N-type region, namely, a cathode region. Thereafter, a third dielectric film (not shown) is further deposited on the back side of the silicon substrate 1 so as to protect the back side.

Next, in an eleventh step, the first dielectric film on the front side of the silicon substrate 1 is removed.

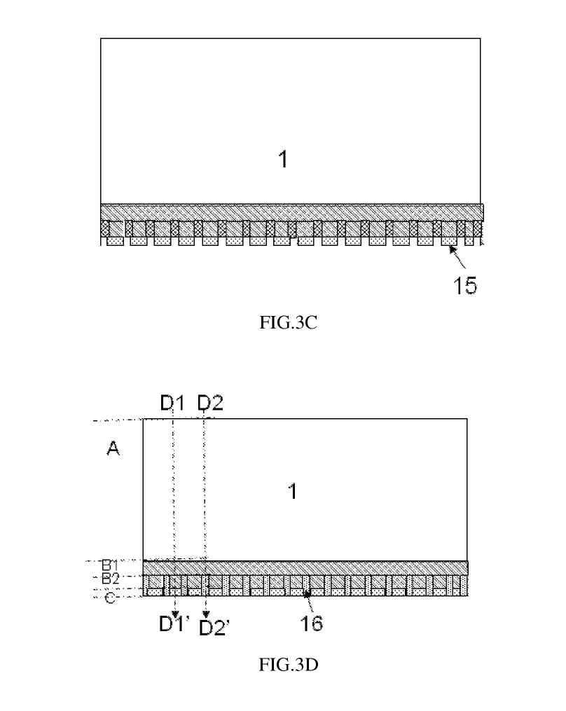

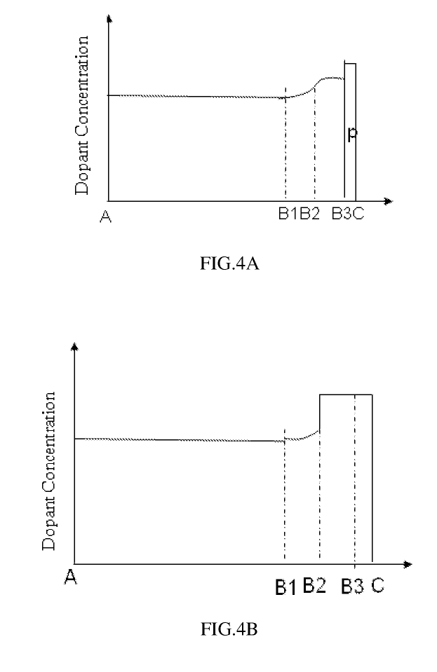

FIG. 4A illustrates dopant concentration distribution along the line D1-D1′ of FIG. 3D, wherein the region B3-C is a P-type region while regions A-B1, B1-B2 and B2-B3 are all N-type regions. As illustrated, the region B1-B2 has a dopant concentration that is higher than that of the region A-B1 and is lower than that of the region B2-B3. Both the N-type regions B1-B2 and B2-B3 which represent the field stop layers of the IGBT device have a dopant concentration higher than that of the region A-B 1. Similarly, FIG. 4B illustrates dopant concentration distribution along the line D2-D2′ of FIG. 3D, wherein the regions A-B1, B1-B2, B2-B3 and B3-C are all N-type regions. As illustrated, the region B1-B2 has an N-type dopant concentration that is higher than that of the region A-B1 and is lower than those of the regions B2-B3 and B3-C. Furthermore, the regions B2-B3 and B3-C have a same dopant concentration which is as high as to result in a good ohmic contact between an outmost portion of the region B3-C and a back side metal layer.

In order to complete the fabrication of the reverse conducting IGBT semiconductor device in the first embodiment, front-side processes are also needed in addition to the back-side processes as described in conjunction with the foregoing description of the first to eleventh steps. In the first embodiment, all front-side processes are carried out following the above eleventh step and include those similar to the front-side processes known by those skilled in the art of vertical double diffused metal oxide semiconductor (VDMOS). As shown in FIG. 2, these front-side processes may include: forming the gate oxide 5 and the polysilicon gate 6 on top of the silicon substrate 1; forming the P-well 7 and the N+ source 8; forming an interlayer dielectric film 9 that encapsulates the polysilicon gate 6; forming the contact hole 10; forming the P+ contact implantation region 11; forming a metal electrode 12 for the source and another metal electrode (not shown) for the polysilicon gate 6; and forming the back side metal layer 14, wherein the portion of the silicon substrate 1 between the P-well 7 and the field stop structure 3 serves as an N-type drift region of the device.

In a second embodiment of the present invention, more integrations can be realized between front-side and back-side processes adopted in the method for manufacturing a reverse conducting IGBT semiconductor device. Steps of the method will be specified in details in the following description.

In a first step, as illustrated in FIG. 3A, an N-type silicon substrate 1 with a dopant concentration C1 of 2.4e13 cm⁻³, a resistivity of 90 Ω·cm and a thickness of greater than 700 μm is provided.

Thereafter, front-side processes similar with those known by those skilled in the art of VDMOS are carried out, including: forming gate oxide 5 and a polysilicon gate 6 on top of the silicon substrate 1; and forming a P-well 7 and an N+ source 8. Alternatively, before the formation of the gate oxide 5 and other subsequent front-side processes, an N-type epitaxial layer may be first formed over a front side surface of the silicon substrate 1.

Next, a first dielectric film (not shown) is deposited over the front side of the silicon substrate 1 so as to protect the front side. In this embodiment, the first dielectric film is an oxide film and has a thickness of 5000 Å to 20000 Å.

After that, the back side of the N-type silicon substrate 1 is grinded to a desired thickness of 500 μm to 700 μm. Herein, in FIG. 3A, the cross section A represents a plane of the front side of the silicon substrate 1 whilst the cross section C represent a plane of the back side surface of the grinded silicon substrate 1.

In a second step, as shown in FIG. 3A, trenches are formed in a portion of the silicon substrate 1 on the back side using a lithographic and etching process, wherein the portion is represented by the region between the cross sections B2 and C. The trenches have a depth d2 of 1 μm to 50 μm, and may preferably have a depth of 2 μm to 10 μm. Moreover, a ratio of a width of the trenches to a spacing b between adjacent trenches is 1/50 to ½, and may preferably be 1/20 to ½.

Thereafter, in a third step, as shown in FIG. 3A, a vertical implantation and multiple tilted implantations of N-type ions are performed in the silicon substrate 1 from the back side where the trenches have been formed. The N-type ions of the vertical implantation are selenium ions or sulfur ions which are implanted with an energy of 200 KeV to 3000 KeV and a dose of 1e11 cm⁻² to 1e14 cm⁻². Moreover, the N-type ions of the tilted implantations are selenium ions or sulfur ions, and the tilted implantations may be performed with at least two different angles. In a preferred embodiment, the multiple tilted implantations include 10-degree-tilted implantation(s) and 45-degree-tilted implantation(s) and are performed at a dose of 2e11 cm⁻² to 5e12 cm⁻².

Next, in a fourth step, as shown in FIG. 3A, a field stop structure 3 is formed by activating the ions implanted into the substrate through using an annealing process to facilitate their diffusion. In this embodiment, the annealing process is a thermal annealing process performed at a temperature of 700° C. to 900° C. for 1 hour to 10 hours. In another embodiment, the annealing process in this step may be a laser annealing process. Moreover, every two adjacent ones of the trenches may be separated from each other with a proper spacing b such that the ions implanted are able to diffuse across half width of this spacing so that every portion of the spaces between adjacent trenches are contained with activated ions.

The field stop structure 3 is formed in a portion of the silicon substrate 1 with a thickness d represented by the region between the cross sections B1 and C in the figure. Additionally, the field stop structure 3 is divided by the trenches into a first field stop layer located at bottom of the trenches and a plurality of second field stop layers each located between two adjacent trenches. Furthermore, the first field stop layer is formed in a portion represented by the region between the cross sections B1 and B2 and has a thickness of greater than 5 μm.

After that, in a fifth step, as shown in FIG. 3B, a second dielectric film 4 is deposited over the back side of the silicon substrate 1 where the field stop structure 3 has been formed and thereafter the second dielectric film 4 is etched back such that the etched second dielectric film 4 partially fills each of the trenches.

Next, in a sixth step, as shown in FIG. 3C, P-type ions are implanted in the silicon substrate 1 from the back side to form ion implantation regions, which serve as a collector region 15 of the IGBT device, in top portions of the second field stop layers. In this embodiment, the P-type ions implanted for forming the collector region 15 are boron ions which are implanted with an energy of 30 KeV to 100 KeV and a dose of 3e14 cm⁻² to 5e15 cm⁻². Moreover, the collector region 15 has a depth of 0.1 μm to 2 μm, and may preferably have a depth of 0.5 μm to 2 μm.

Thereafter, in a seventh step, as shown in FIG. 3D, the second dielectric film 4 is removed.

Next, in an eighth step, as shown in FIG. 3D, an N-type polysilicon or epitaxial layer 16 is deposited, completely filling the trenches and covering the rest portion of the back side surface of the silicon substrate 1 as well as the first dielectric film on the front side of the silicon substrate 1. Additionally, the polysilicon or epitaxial layer 16 has an N-type dopant concentration of 1e19 cm⁻³ to 5e20 cm⁻³.

After that, in a ninth step, as shown in FIG. 3D, the polysilicon or epitaxial layer 16 over the first dielectric film on the front side of the silicon substrate 1 is removed.

In a tenth step, as shown in FIG. 3D, the polysilicon or epitaxial layer 16 higher than the trenches and over the rest portion of the back side surface of the silicon substrate 1 is removed, so that only the N-type polysilicon or epitaxial layer 16 that completely fills the trenches and serves as the first electrode region of the FRD is remained. The first electrode region is an N-type region, namely, a cathode region. Thereafter, a third dielectric film (not shown) is further deposited on the back side of the silicon substrate 1 to protect the back side.

Next, in an eleventh step, the first dielectric film on the front side of the silicon substrate 1 is removed.

After that, the silicon substrate is turned over to further receive following front-side processes: forming an interlayer dielectric film 9 that encapsulates the polysilicon gate 6; forming a contact hole 10; forming a P+ contact implantation region 11; forming a metal electrode 12 for the source and another metal electrode (not shown) for the polysilicon gate 6; and forming a back side metal layer 14. In the resulting device, the portion of the silicon substrate 1 between the P-well 7 and the field stop structure 3 serves as an N-type drift region of the device.

In a third embodiment of the present invention, a method for manufacturing a reverse conducting IGBT semiconductor device can be implemented with a reduced process complexity. Steps of the method will be specified in details in the following description with reference to FIG. 2.

In a first step, an N-type silicon substrate 1 with a dopant concentration C1 of 2.4e13 cm⁻³, a resistivity of 90 Ω·cm and a thickness of greater than 700 μm is first provided. After that, a first dielectric film (not shown) is deposited over a front side of the silicon substrate 1 so as to protect the front side. In this embodiment, the first dielectric film is an oxide film and has a thickness of 5000 Å to 20000 Å.

Next, the back side of the N-type silicon substrate 1 is grinded to a desired thickness of 500 μm to 700 μm. Herein, in FIG. 2, the cross section A represents a plane of the front side of the silicon substrate 1 whilst the cross section C represents a plane of the back side surface of the grinded silicon substrate 1.

In a second step, trenches are formed in a portion of the back side of the silicon substrate 1 by using a lithographic and etching process, wherein the portion is represented by the region between the cross sections B2 and C. The trenches have a depth d2 of 1 μm to 50 μm, and may preferably have a depth of 2 μm to 10 μm. Moreover, a ratio of a width of the trenches to a spacing b between adjacent trenches is 1/50 to ½, and may preferably be 1/20 to ½.

Thereafter, in a third step, a vertical implantation and multiple tilted implantations of N-type ions are performed in the silicon substrate 1 from the back side where the trenches have been formed. The N-type ions of the vertical implantation are phosphorus ions which are implanted with an energy of 200 KeV to 3000 KeV and a dose of 1e11 cm⁻² to 1e14 cm⁻². Moreover, the N-type ions of the tilted implantations are phosphorus ions or arsenic ions, and the tilted implantations may be performed with at least two different angles. In a preferred embodiment, the multiple tilted implantations may adopt a combination of 10-degree-tilted implantation(s) and 45-degree-tilted implantation(s) with a dose of 2e11 cm⁻² to 5e12 cm⁻².

Next, in a fourth step, a field stop structure 3 is formed by activating the ions by using an annealing process for facilitating their diffusion. In this embodiment, the annealing process is a thermal annealing process performed for 2 hours to 10 hours at a temperature of 900° C. to 1250° C.

The field stop structure 3 is formed in a portion of the silicon substrate 1 with a thickness d represented by the region between the cross sections B1 and C in the figure. Additionally, the field stop structure 3 is divided by the trenches into a first field stop layer located at bottom of the trenches and a plurality of second field stop layers each located between two adjacent trenches. Furthermore, the first field stop layer is formed in a portion represented by the region between the cross sections B1 and B2 and has a thickness of greater than 5 μm.

Next, in a fifth step, the silicon substrate is turned over and the first dielectric film is removed. Thereafter, front-side processes similar with those known by those skilled in the art of VDMOS are carried out, including: forming gate oxide 5 on top of the silicon substrate 1, during which an oxide film will also be formed on the back side of the silicon substrate 1; and removing portions of the oxide film in the trenches using a back-side etching process.

After that, polysilicon deposition is performed to form a polysilicon gate 6 on the front side of the silicon substrate 1 and a polysilicon or an epitaxial layer 16 in the trenches on the back side. The polysilicon or epitaxial layer 16 completely fills the trenches and has an N-type dopant concentration of 1e19 cm⁻³ to 5e20 cm⁻³.

Next, in a sixth step, the polysilicon or epitaxial layer 16 higher than the trenches and over the rest portion of the back side surface of the silicon substrate 1 is removed, so that only N-type polysilicon or epitaxial layer 16 that completely fills the trenches and serves as a first electrode region of the FRD is remained. The first electrode region is an N-type region, namely, a cathode region.

Thereafter, the silicon substrate is again turned over to further receive following front-side processes that are similar with those known by those skilled in the art of VDMOS: forming a P-well 7 and an N+ source 8; forming an interlayer dielectric film 9 that encapsulates the polysilicon gate 6; forming a contact hole 10; forming a P+ contact implantation region 11; and forming a metal electrode 12 for the source and another metal electrode (not shown) for the polysilicon gate 6.

In a seventh step, P-type ions are implanted in the silicon substrate 1 (where the first electrode region has been formed and the front-side processes described above have been applied) from the back side to form ion implantation regions, which serve as a collector region 15 of the IGBT device, in top portions of the second field stop layers. In this embodiment, the collector region 15 has a thickness of 0.5 μm to 2 μm. The P-type ions implanted for forming the collector region 15 are boron ions which are implanted with an energy of 30 KeV to 100 KeV and a dose of 3e14 cm⁻² to 5e15 cm⁻². Moreover, a bulk concentration of the collector region 15 is lower than ⅕ of the N-type dopant concentration of the polysilicon or epitaxial layer 16 in the trenches.

After that, at a last step, a back side metal layer 14 is formed.

While specific embodiments have been presented in the foregoing description, they are not intended to limit the invention in any way. Those skilled in the art can make various modifications and variations without departing from the scope of the invention. Thus, it is intended that the present invention covers all such modifications and variations.

What is claimed is:

1. A field stop structure, formed in a silicon substrate having a first conductivity type, a plurality of trenches being formed on a back side of the silicon substrate, the field stop structure comprising:
a first field stop layer of the first conductivity type located in a portion of the silicon substrate at bottom of the plurality of trenches, the first field stop layer being laterally continuous; and
a plurality of second field stop layers of the first conductivity type, each being located between two adjacent trenches and being joined with the first field stop layer.

2. The field stop structure of claim 1, wherein the first conductivity type is N-type, and wherein each of the first field stop layer and the second field stop layers contains a dopant selected from a group consisting of phosphorus, arsenic, selenium, sulfur and combinations thereof.

3. The field stop structure of claim 1, wherein each of the plurality of trenches has a depth of 1 μm to 50 μm, and wherein the first field stop layer has a thickness of greater than 5 μm.

4. The field stop structure of claim 1, wherein a ratio of a width of each trench to a spacing between adjacent trenches is 1/50 to ½.

5. The field stop structure of claim 1, wherein the field stop structure has a carrier concentration greater than that of the silicon substrate.

6. A reverse conducting insulated gate bipolar transistor (IGBT) semiconductor device comprising the field stop structure of claim 1, the semiconductor device being integrated with an IGBT device and a fast recovered diode (FRD), the semiconductor device further comprising:
a first electrode region of the FRD consisting of a polysilicon or an epitaxial layer of the first conductivity type formed in the plurality of trenches;
a collector region of the IGBT device consisting of ion implantation regions of a second conductivity type formed in top portions of the second field stop layers; and
a back-side metal layer formed on the back side of the silicon substrate, the back-side metal layer being connected with the collector region of the IGBT device and the first electrode region of the FRD and serving as an electrode for the collector region of the IGBT device and the first electrode region of the FRD.

7. A method for forming field stop structure, comprising:
forming a plurality of trenches ion a back side of a silicon substrate having a first conductivity type;
performing, by using ions of the first conductivity type, a vertical implantation and multiple steps of tilted implantations on the back side of the silicon substrate; and
performing an annealing process to activate and cause diffusion of the ions so as to form a laterally continuous first field stop layer in a portion of the silicon substrate at bottom of the plurality of trenches and a plurality of second field stop layers, each second field stop layer being located between two adjacent trenches and being joined with the first field stop layer.

8. The method of claim 7, wherein the first conductivity type is N-type, and the second conductivity type is P-type.

9. The method of claim 7, wherein each of the plurality of trenches has a depth of 1 μm to 50 μm, and wherein the first field stop layer has a thickness of greater than 5 μm.

10. The method of claim 7, wherein a ratio of a width of each trench to a spacing between adjacent trenches is 1/50 to ½.

11. The method of claim 7, wherein the vertical implantation is performed with an energy of 200 KeV to 3000 KeV and a dose of 1e11 cm⁻² to 1e14 cm⁻², and wherein the multiple steps of tilted implantations are performed with at least two different angles and an implantation dose of 2e11 cm⁻² to 5e12 cm⁻².

12. The method of claim 8, wherein the N-type ions used in the vertical implantation are phosphorus ions and the N-type ions used in the tilted implantations are phosphorus ions or arsenic ions, and wherein the annealing process is a thermal annealing process performed at a temperature of 700° C. to 1250° C.

13. The method of claim 8, wherein the N-type ions used in the vertical implantation are selenium ions or sulfur ions and the N-type ions used in the tilted implantations are selenium ions or sulfur ions, and wherein the annealing process is a thermal annealing process performed for 1 hour to 10 hours at a temperature of 700° C. to 900° C.

14. The method of claim 7, wherein the annealing process is a laser annealing process.

15. A method for manufacturing reverse conducting insulated gate bipolar transistor (IGBT) semiconductor device, the semiconductor device being integrated with an IGBT device and a fast recovered diode (FRD), the method comprising the steps of:
depositing a first dielectric film over a front side of a silicon substrate having a first conductivity type so as to protect the front side of the silicon substrate;
forming a plurality of trenches on a back side of the silicon substrate;
performing, by using ions of the first conductivity type, a vertical implantation and multiple steps of tilted implantations on the back side of the silicon substrate;
performing an annealing process to activate and cause diffusion of the ions so as to form a laterally continuous first field stop layer in a portion of the silicon substrate at bottom of the plurality of trenches and a plurality of second field stop layers, each second field stop layer being located between two adjacent trenches and being joined with the first field stop layer; and
forming a first electrode region of the FRD and a collector region of the IGBT device.

16. The method of claim 15, wherein the step of forming a first electrode region of the FRD and a collector region of the IGBT device comprises:
depositing a second dielectric film over the back side of the silicon substrate and etching back the second dielectric film such that the etched second dielectric film partially fills each of the plurality of trenches;
forming ion implantation regions of a second conductivity type, which serve as the collector region of the IGBT device, in top portions of the second field stop layers, by performing an implantation of ions of the second conductivity type into the back side of the silicon substrate;
removing the second dielectric film; and
filling a polysilicon or an epitaxial layer of the first conductivity type, which serves as the first electrode region of the FRD, in the plurality of trenches.

17. The method of claim 16, wherein the first conductivity type is N-type and the second conductivity type is P-type.

18. The method of claim 17, wherein ions of the second conductivity type are boron ions and are implanted with an energy of 30 KeV to 100 KeV and a dose of 3e14 cm⁻² to 5e15 cm⁻².

19. The method of claim 17, wherein the polysilicon or the epitaxial layer has a dopant concentration of 1e19 cm⁻³ to 5e20 cm⁻³.

20. The method of claim 15, wherein the step of forming a first electrode region of the FRD and a collector region of the IGBT device comprises:
filling a polysilicon or an epitaxial layer of the first conductivity type, which serves as the first electrode region of the FRD, in the plurality of trenches; and
forming ion implantation regions of a second conductivity type, which serve as the collector region of the IGBT device, in top portions of the second field stop layers, by performing an implantation of ions of the second conductivity type into the back side of the silicon substrate.

21. The method of claim 20, wherein the first conductivity type is N-type and the second conductivity type is P-type.

22. The method of claim 21, wherein the polysilicon or the epitaxial layer has a dopant concentration of 1e19 cm⁻³ to 5e20 cm⁻³.

23. The method of claim 21, wherein ions of the second conductivity type are boron ions and are implanted with an energy of 30 KeV to 100 KeV and a dose of 3e14 cm⁻² to 5e15 cm⁻².
